(19) United States
(12) Patent Application Publication
(10) Pub. No.: US 2010/0270591 A1
(43) Pub. Date: Oct. 28, 2010

(54) HIGH-ELECTRON MOBILITY TRANSISTOR

(75) Inventor: Doyeol AHN, Seoul (KR)

Correspondence Address: Workman Nydegger;1000 Eagle Gate Tower, 60 East South Temple, Salt Lake City, UT, 84111, US

(73) Assignee: University of Seoul Industry Cooperation Foundation, Seoul (KR)

(21) Appl. No.: 12/430,331

(22) Filed: Apr. 27, 2009

(51) Int. Cl. H01L 29/778; H01L 21/335

(52) U.S. Cl. 257/194; 438/172; 257/E29.246; 257/E21.403

(57) ABSTRACT

Disclosed are high electron mobility transistors (HEMTs). In some embodiments, a HEMT includes a channel layer composed of a first compound semiconductor material and one or more barrier layers disposed on either one side or both sides of the channel layer and composed of a second compound semiconductor material.

### BACKGROUND

High electron mobility transistors (HEMTs) are field effect transistors that incorporate a junction between two materials with different band gaps, i.e., a heterojunction as the channel instead of a doped region, as is generally the case for MOSFETs. HEMTs are also known as heterostructure field effect transistors (HFETs) or modulation-doped field effect transistors (MODFETs).

A commonly used material combination for a HEMT is GaAs with AlGaAs. However, GaAs/AlGaAs based HEMTs are not suitable for high power and high frequency applications because of their relatively small band gap and relatively small breakdown voltage. Research is being conducted to enhance the high power and high frequency applications of HEMTs.

### SUMMARY

In one embodiment, a high electron mobility transistor (HEMT) includes a channel layer composed of a first compound semiconductor material and one or more barrier layers disposed on either one side or both sides of the channel layer and composed of a second compound semiconductor material. The composition of the barrier layer is adjusted to reduce an internal polarization field in the channel layer.

The foregoing summary is illustrative only and is not intended to be in any way limiting. In addition to the illustrative aspects, embodiments, and features described above, further aspects, embodiments, and features will become apparent by reference to the drawings and the following detailed description.

### BRIEF DESCRIPTION OF THE FIGURES

FIG. 1 is a schematic diagram of an illustrative embodiment of a HEMT.

FIG. 2 is a schematic diagram showing the band gaps of the HEMT of FIG. 1.

FIG. 3 is a schematic diagram of an illustrative embodiment of a III-V compound semiconductor based HEMT.

FIG. 4 is a graph showing internal polarization field as a function of In composition of the AlGaInN barrier layer shown in FIG. 3.

FIG. 5 is a graph showing the relationship between In composition of the InGaN channel layer and In composition of the AlGaInN barrier layer shown in FIG. 3.

FIG. 6 is a schematic diagram of an illustrative embodiment of a II-VI compound semiconductor based HEMT.

FIG. 7 is a graph showing internal polarization field as a function of Mg composition of the MgZnO barrier layer and Cd composition of the CdZnO channel layer shown in FIG. 6.

FIG. 8 is a graph showing the relationship between Mg composition of the MgZnO barrier layer and Cd composition of the CdZnO channel layer shown in FIG. 6.

FIG. 9 is a schematic diagram of another illustrative embodiment of a HEMT.

FIGS. 10(a) through 10(c) are schematic diagrams showing suitable band gaps of the HEMT of FIG. 9.

FIGS. 11(a) through 11(f) are schematic diagrams illustrating an illustrative embodiment of a method for fabricating a HEMT.

### DETAILED DESCRIPTION

In one embodiment, a high electron mobility transistor (HEMT) includes a channel layer composed of a first compound semiconductor material and one or more barrier layers disposed on either one side or both sides of the channel layer and composed of a second compound semiconductor material. The composition of the barrier layer can be adjusted to reduce an internal polarization field in the channel layer.

A band gap of the first compound semiconductor material may be smaller than that of the second compound semiconductor material. The second compound semiconductor material can include a ternary or a quaternary compound semiconductor material. The first and second compound semiconductor materials can each include a III-V compound semiconductor material or a II-VI compound semiconductor material. As an example, the first compound semiconductor material can include GaN, InGaN, AlN, AlP, AlAs, GaP, GaAs, InN, InP, InAs, AlGaN, AlGaP, AlGaAs, InGaN, InGaP, InGaAs, InAlN, InAlP, InAlAs, AlGaInN, AlGaInP, AlGaInAs, ZnO, ZnS, CdO, CdS, CdZnS, CdZnO, MgZnO, MgZnS, CdMgZnO, or CdMgZnS. Further, the second compound semiconductor material can include AlInGaN, InGaN, AlGaN, AlGaP, AlGaAs, InGaN, InGaP, InGaAs, InAlN, InAlP, InAlAs, AlGaInP, AlGaInAs, CdZnO, CdZnS, MgZnO, MgZnS, CdMgZnO, or CdMgZnS.

The HEMT can further include a gate contact, a source contact, and a drain contact disposed on the barrier layer.

The barrier layer may include a multiple number of sub-barrier layers. Each of the sub-barrier layers can be composed of a III-V compound semiconductor material or a II-VI compound semiconductor material. Each of the sub-barrier layers can include, for example, AlInGaN, InGaN, AlGaN, AlGaP, AlGaAs, InGaN, InGaP, InGaAs, InAlN, InAlP, InAlAs, AlGaInP, AlGaInAs, CdZnS, CdZnO, MgZnO, MgZnS, CdMgZnO, or CdMgZnS. The band gaps of the sub-barrier layers may be adjusted to reduce the internal polarization field in the channel layer. The composition of each sub-barrier layer may be controlled to have a step shape band gap, a gradually increasing band gap, or a multi-quantum well band gap.

The channel layer may be composed of InₓGa₁₋ₓN (0≦x≦1) and the barrier layer may be composed of AlInyGa1−yN (0≦y≦1). The variable x may be in the range of about 0 and 0.30 and the variable y may be in the range of about 0.01 and 0.30. The relation of the variables x and y may be linear.

Alternatively, the channel layer may be composed of CdₓZn₁₋ₓO (0≦x≦1) and the barrier layer may be composed of Mg_{y}Zn_{1-y}O (0≦y≦1). The variable x may be in the range of about 0 and 0.20 and the variable y may be in the range of about 0.01 and 0.80. The relation of the variables x and y may be logarithmic.

The thickness of the channel layer may be in the range of about 0.1 nm and 300 nm. The thickness of the barrier layer may be in the range of about 0.1 nm and 500 nm.

In another embodiment, a method for fabricating a high electron mobility transistor (HEMT) includes forming a channel layer composed of a first compound semiconductor material, and disposing one or more barrier layers on either one side or both sides of the channel layer. The barrier layer can be composed of a second compound semiconductor material. The composition of the barrier layer may be adjusted to reduce an internal polarization field in the channel layer.

The first and second compound semiconductor materials can each include a III-V compound semiconductor material or a II-VI compound semiconductor material.

A multiple number of sub-barrier layers can be formed on either one side or both sides of the channel layer. Each of the sub-barrier layers may be composed of a III-V compound semiconductor material or a II-VI compound semiconductor material.

In the following detailed description, reference is made to the accompanying drawings, which form a part hereof. In the drawings, similar symbols typically identify similar components, unless context dictates otherwise. The illustrative embodiments described in the detailed description, drawings, and claims are not meant to be limiting. Other embodiments may be utilized, and other changes may be made, without departing from the spirit or scope of the subject matter presented herein. It will be readily understood that the aspects of the present disclosure, as generally described herein, and illustrated in the Figures, can be arranged, substituted, combined, separated, and designed in a wide variety of different configurations, all of which are explicitly contemplated herein.

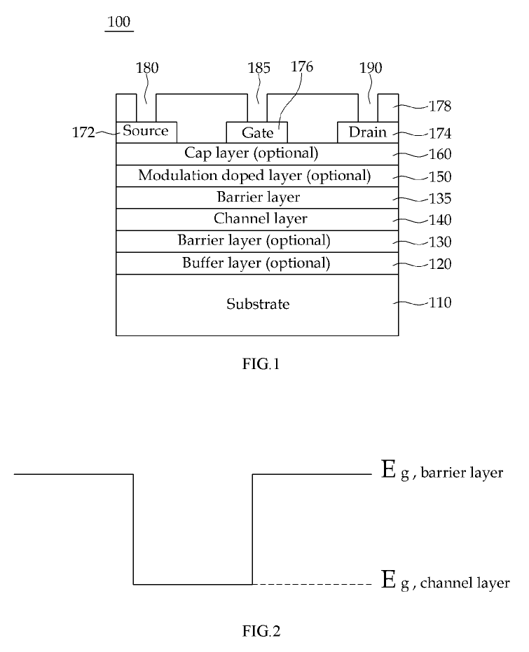

With reference to FIGS. 1 and 2, a high electron mobility transistor (HEMT) in accordance with the present disclosure will now be described. FIG. 1 is a schematic diagram of an illustrative embodiment of a HEMT 100. FIG. 2 is a schematic diagram showing the band gaps of HEMT 100 of FIG. 1.

As shown in FIG. 1, HEMT 100 includes a substrate 110, a buffer layer 120 (which is optional) located on substrate 110, a lower barrier layer 130 (which is optional) on buffer layer 120, a channel layer 140 on barrier layer 130, an upper barrier layer 135 on channel layer 140, a modulation doped layer 150 (which is optional) on upper barrier layer 135, a cap layer 160 (which is optional) on modulation doped layer 150, a source contact 172, a drain contact 174, and a gate contact 176 on cap layer 160, and a passivation layer 178 covering at least portions of source, drain, and gate contacts 172, 174, and 176 and cap layer 160 not covered by contacts 172, 174, and 176. As depicted in FIG. 1, HEMT 100 may include a multiple number of barrier layers (e.g., upper and lower barrier layers 130 and 135) on both sides of channel layer 140. In cases where HEMT 100 includes multiple barrier layers (e.g., upper and lower barrier layers 130 and 135) on both sides of channel layer 140, the carrier confinement is improved, and this may allow for the achievement of higher carrier mobility. Those of ordinary skill in the art will appreciate that, for any of the HEMTs described in the present disclosure, an element or a layer may be located on a lower layer without one or more of the intervening optional layers. For example, in HEMT 100, in the instance optional modulation doped layer 150 is not provided, optional cap layer 160, if provided, may be on barrier layer 135. Similarly, in the instance optional buffer layer 120 and optional barrier layer 130 are not provided, channel layer 140 may be on substrate 110.

Substrate 110 may include, but is not limited to, c-face (0001) or a-face (1120) oriented sapphire (Al₂O₃), silicon carbide (SiC), aluminum nitride (AlN), aluminum gallium nitride (AlGaN), gallum nitride (GaN), silicon (Si), or spinel (MgAl₂O₄). Buffer layer 120, when present, may provide substrate 110 with an appropriate crystalline transition between substrate 110 and the other layers of HEMT 100. For example, in cases where substrate 110 and lower barrier layer 130 have different lattice matches, buffer layer 120 may be provided between substrate 110 and lower barrier layer 130 to reduce the lattice match difference. Accordingly, buffer layer 120 can be selected by considering (i.e., based on) substrate 110 and the layers to be formed on substrate 110. By way of example, buffer layer 120 may include, but is not limited to, aluminum nitride (AlN), aluminum gallum nitride (AlGaN), gallum nitride (GaN), SiC or ZnO-based compound semiconductor material, such as zinc oxide (ZnO) or magnesium zinc oxide (MgZnO). Buffer layer 120 may have a thickness of about 0.1 μm to 300 μm.

Channel layer 140 may include a III-V compound semiconductor material or a II-VI compound semiconductor material. By way of example, a III-V compound semiconductor material for channel layer 140 may include, but is not limited to, GaN, InGaN, AlN, AlP, AlAs, GaP, GaAs, InN, InP, InAs, AlGaN, AlGaP, AlGaAs, InGaN, InGaP, InGaAs, InAlN, InAlP, InAlAs, AlGaInN, AlGaInP, and AlGaInAs. A II-VI compound semiconductor material for channel layer 140 may include, but is not limited to, ZnO, ZnS, CdO, CdS, CdZnS, MgZnO, CdZnO, MgZnS, CdMgZnO, and CdMgZnS. Channel layer 140 may have a thickness of several nanometers to several hundred nanometers (nm). For example, channel layer 140 can have a thickness of about 0.1 nm to 300 nm, or about 1 nm to 50 nm.

Upper barrier layer 135 and lower barrier layer 130, when present, may include a III-V compound semiconductor material or a II-VI compound semiconductor material having a wider bad gap than that of channel layer 140. For example, upper barrier layer 135 and lower barrier layer 130 may include a ternary or a quaternary compound semiconductor material. By way of example, upper barrier layer 135 and lower barrier layer 130 may include, but is not limited to, AlGaN, AlGaP, AlGaAs, InGaN, InGaP, InGaAs, InAlN, InAlP, InAlAs, AlGaInN, AlGaInP, AlGaInAs, CdZnS, MgZnO, CdZnO, MgZnS, CdMgZnO, or CdMgZnS. Moreover, upper and lower barrier layers 135 and 130 each may have a thickness of about 0.1 nm to 500 nm. In some examples, the thicknesses of upper and lower barrier layers 135 and 130 each may be in the range of about 1 nm and 100 nm.

Modulation doped layer 150, when present, may be doped with a donor, such as Si or Ge, or doped with an acceptor, such as Mg or Zn, to provide carriers to upper barrier layer 135 or channel layer 140. Examples of modulation doped layer 150 include III-V compound semiconductor materials, such as AlGaN, GaN, and InGaN, and II-VI compound semiconductor materials, such as ZnO and MgZnO, but modulation doped layer 150 is not limited to these semiconductor materials. Modulation doped layer 150 may have a thickness of about 1 nm to 100 nm.

Cap layer 160, when present, may include, but is not limited to, a III-V compound semiconductor material, such as AlGaN, GaN, and InGaN, or a II-VI compound semiconductor material, such as ZnO and MgZnO. Cap layer 160 can be doped with a donor or an acceptor, or be undoped. For example, cap layer 160 may be undoped to improve the characteristics of the Schottky gate contact of the transistor. In some examples, cap layer 160 may have a thickness of about 1 nm to 50 nm.

Gate contact 176 and source and drain contacts 172 and 174 can be arranged in the same layer as depicted in FIG. 1. However, in other embodiments, gate contact 176 and source and drain contacts 172 and 174 can be arranged in a different layer. For example, an additional layer (not shown) to facilitate ohmic contact of source and drain contacts 172 and 174 can be provided between cap layer 160 and source and drain contacts 172 and 174. By way of example, source and drain contacts 172 and 174 can be formed of titanium (Ti), aluminum (Al), nickel (Ni), aurum (Au) or alloys thereof and gate contact 176 can be formed of titanium (Ti), platinum (Pt), chromium (Cr), nickel (Ni), aurum (Au), or alloys thereof.

Passivation layer 178, which covers source, drain, and gate contacts 172, 174 and 176, can be formed of silicon nitride or silicon dioxide. Passivation layer 178 includes gaps or windows 180, 185 and 190 that expose at least a portion of the contacts (e.g., source contact 172, drain contact 174, and gate contact 176) and through which contacts may be connected to respective wire bonds (not shown), which, in turn, may be connected to an external circuit (not shown).

As depicted in FIG. 1, HEMT 100 forms a heterojunction between channel layer 140 and either of or both of lower barrier layer 130 and upper barrier layer 135, which are composed of semiconductor materials with different band gaps. A quantum well is formed due to the different band gaps between channel layer 140 and lower barrier layer 130 and upper barrier layer 135. A two-dimensional electron gas (2DEG) may be formed at the heterojunction of two semiconductor materials with different bandgap energies. 2DEG is an accumulation layer in the smaller band gap material and contains a very high sheet carrier concentration in the order of about 10¹² to 10¹³ carriers per square centimeter (carriers/cm²). Thus, the carriers originated in the wider band gap semiconductor transfer to 2DEG, allowing for high electron mobility due to reduced ionized impurity scattering in the smaller band gap semiconductor.

Lower and upper barrier layers 130 and 135 are selected to have the band gap wider than the band gap of channel layer 140. Accordingly, a band gap difference is formed between channel layer 140 and lower and upper barrier layers 130 and 135, as depicted in FIG. 2. By using the differences between a band gap (E_{g, channel layer}) of channel layer 140 and a band gap (E_{g, barrier layer}) of lower and upper barrier layers 130 and 135, a heterojunction can be formed in channel layer 140, and thus a quantum well can be formed in the heterojunction, as described. Further, 2DEC region for carrier confinement can be formed in channel layer 140 in contact with lower and upper layers 130 and 135. Here, E_{g} indicates E_{c}-Eᵥ, where E_{c} refers to an energy level at a conduction band of the compound of the channel or barrier layer, and Eᵥ refers to an energy level at a valence band of the compound of the channel or barrier layer.

High performance of HEMT 100 depends on the mobility characteristics of electrons in channel layer 140. The electron mobility is determined by electron scatterings in channel layer 140. A scattering rate is affected by an electron-phonon scattering and a surface charging scattering induced by an internal polarization field of the quantum well.

The internal polarization field in the quantum well arises from a spontaneous polarization P_{SP} and a piezoelectric polarization P_{PZ}. Piezoelectric polarization P_{PZ} refers to a polarization that arises from the electric potential generated in response to applied mechanical stress, such as a strain of a layer. Spontaneous polarization P_{SP} refers to a polarization that arises in ferroelectrics without external electric field. Although piezoelectric polarization P_{PZ} can be reduced by the reduction of the strain, spontaneous polarization P_{SP} remains in the quantum well. For additional detail on the internal polarization field, see Ahn et al., “Spontaneous and piezoelectric polarization effects in wurtzite ZnO/MgZnO quantum well lasers”, Appl. Phys. Lett. Vol. 87, p. 253509 (2005), which is incorporated by reference herein in its entirety.

Thus, in order to increase the electron mobility of HEMT 100, a total internal polarization field that includes spontaneous polarization P_{SP} and piezoelectric polarization P_{PZ}, is reduced. Total internal polarization field F_{z}^{w} in the quantum well of channel layer 140 can be determined from the difference between the sum of spontaneous polarization P_{SP} and piezoelectric polarization P_{PZ} in the quantum well in channel layer 140 and the sum of spontaneous polarization P_{SP} and piezoelectric polarization P_{PZ} in lower and upper barrier layers 130 and 135, as represented by Equation (1) below.

F_{Z}^{W}=[(P_{SP}^{b}+P_{PZ}^{b})−(P_{SP}^{w}+P_{PZ}^{w})]/(∈^{w}+∈^{b}L_{w}/L_{b}) Equation (1)

where P is the polarization, the superscript w and b denote the quantum well formed in channel layer 140 and lower or upper barrier layer 130 or 135 respectively, L is the thickness of the quantum layer or lower or upper barrier layer 130 or 135, and ∈ is a static dielectric constant.

In one embodiment, total internal polarization field F_{z}^{W} can have a value of zero by making the sum (P_{SP}^{b}+P_{PZ}^{b}) of the spontaneous and piezoelectric polarizations at lower or upper barrier layer 130 or 135 and the sum (P_{SP}^{w}+P_{PZ}^{w}) of the spontaneous and piezoelectric polarizations at the quantum well the same. For example, this can be achieved by controlling the mole fractions of the compounds in lower or upper barrier layer 130 or 135, with respect to channel layer 140.

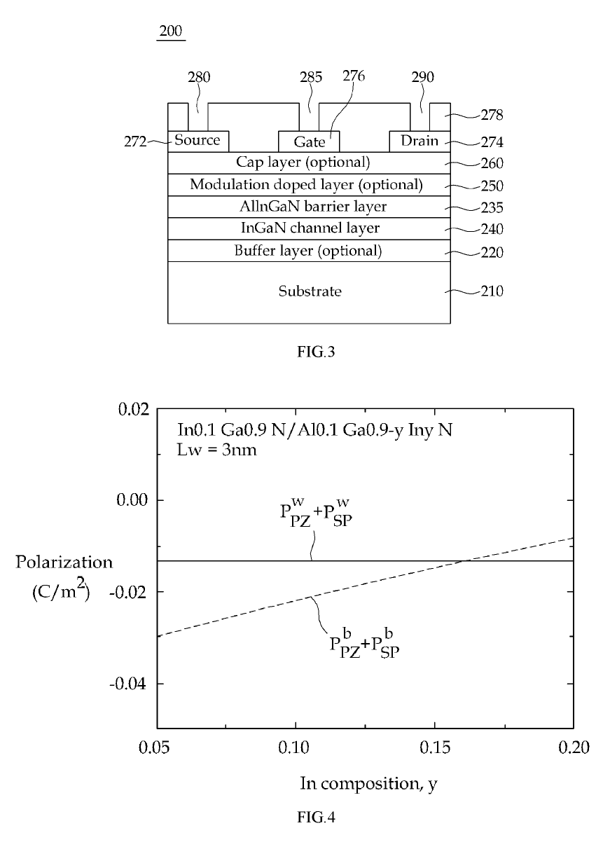

With reference to FIGS. 3-5, a III-V semiconductor based HEMT having a minimized internal polarization field (e.g., total internal polarization field F_{z}^{w}) will now be described. FIG. 3 is a schematic diagram of an illustrative embodiment of a III-V compound semiconductor based HEMT. FIG. 4 is a graph showing internal polarization field as a function of 1n composition of the AlGaInN barrier layer shown in FIG. 3. FIG. 5 is a graph showing the relationship between In composition of the InGaN channel layer and In composition of the AlGaInN barrier layer shown in FIG. 3

As depicted in FIG. 3, a III-V semiconductor based HEMT 200 includes a substrate 210, a buffer layer 220 (which is optional) on substrate 210, an InGaN channel layer 240 on buffer layer 220, an AlInGaN barrier layer 235 on InGaN channel layer 240, a modulation doped layer 250 (which is optional) on AlInGaN barrier layer 235, a cap layer 260 (which is optional) on modulation doped layer 250, a source contact 272, a drain contact 274, and a gate contact 276 on cap layer 260, and a passivation layer 278 covering at least portions of source contact 272, drain contact 274, and gate contact 276 and cap layer 260 not covered by contacts 272, 274, and 276. Passivation layer 278 includes windows 280, 285 and 290 to allow for connections between contacts (e.g., source contact 272, drain contact 274, and gate contact 276) and wire bonds (not shown). Here, a band gap of AlInGaN barrier layer 235 is greater than a band gap of InGaN channel layer 240.

In some embodiments, HEMT 200 may optionally include a lower barrier layer (not shown) under InGaN channel layer 240. Further, channel layer 240 may be composed of a III-V group compound semiconductor material, such as GaN, AlN, AlP, AlAs, GaP, GaAs, InN, InP, InAs, AlGaN, AlGaP, AlGaAs, InGaN, InGaP, InGaAs, InAlN, InAlP, InAlAs, AlGaInN, AlGaInP, or AlGaInAs. Still further, AlInGaN barrier layer 235 may be composed of a ternary or a quaternary III-V group compound semiconductor material, such as InGaN, AlGaN, AlGaP, AlGaAs, InGaN, InGaP, InGaAs, InAlN, InAlP, InAlAs, AlGaInP, or AlGaInAs.

AlInGaN barrier layer 235 may have a thickness of several nanometers to several hundreds nanometers (nm). For example, AlInGaN barrier layer 235 can have a thickness of about 0.1 nm to 500 nm or about 1 nm to 100 nm. InGaN channel layer 240 may have a thickness of several nanometers to several hundreds nanometers (nm). For example, InGaN channel layer 240 can have a thickness of about 0.1 nm to 300 nm, or about 1 nm to 50 nm.

The band gap of InGaN channel layer 240 is smaller than that of AlInGaN barrier layer 235, thereby forming a quantum well in channel layer 240. For example, the band gap of InGaN channel layer 240 is in the range of about 0.7 eV and 3.4 eV, and the band gap of AlInGaN barrier layer 235 is in the range of about 0.7 eV and 6.3 eV. Since the band gap of a compound semiconductor material is determined based on the mole fractions of elements in the compound semiconductor material, the difference between the band gaps of InGaN channel layer 240 and AlInGaN barrier layer 235 can be controlled by adjusting the composition of InGaN channel layer 240, the composition of AlInGaN barrier layer 235, or the compositions of both InGaN channel layer 240 and AlInGaN barrier layer 235. In an illustrative example, Al composition of AlInGaN barrier layer 235 can be controlled so that AlInGaN barrier layer 235 has a larger band gap than that of InGaN channel layer 240. For example, the mole fraction of Al composition in one mole of Al, In, and Ga of AlInGaN barrier layer 235 is in the range of about 0.05 to 0.3 assuming that AlInGaN barrier layer 235 is formed by combining one mole of Al, In, and Ga with one mole of N.

As illustrated with respect to Equation (1) above, the internal polarization field in the quantum well can be reduced by controlling the mole fractions of the compounds in InGaN channel layer 240 and AlInGaN barrier layer 235, which will now be described in detail.

The graph shown in FIG. 4 illustrates an internal polarization field (y-axis) as a function of In composition (x-axis) in AlInGaN barrier layer 235. Here, InGaN channel layer 240 has the compositions of In_{0.1}Ga_{0.9}N and the thickness of 3 nm, and AlInGaN barrier layer 235 has the compositions of Al_{0.1}Ga_{0.9-y}In_{y}N. The variable y may be controlled such that sum P_{PZ} ^{w}+P_{SP}^{w} of the piezoelectric and spontaneous polarizations in InGaN channel layer 240 and sum P_{PZ}^{b}+P_{SP}^{b} of the piezoelectric and the spontaneous polarizations in AlInGaN barrier layer 235 are substantially the same. The cancellation of the sum of piezoelectric and spontaneous polarizations between the quantum well and AlInGaN barrier layer 235 makes the total internal polarization field in InGaN channel layer 240 zero as defined in Equation (1).

As depicted in FIG. 4, the solid line indicates the sum P_{PZ}^{w}+P_{SP}^{w} in the quantum well, and the dotted or dashed line indicates the sum P_{PZ}^{b}+P_{SP}^{b} in AlInGaN barrier layer 235. An experimental test showed that the solid line meets the dotted line when the variable y is approximately 0.16. Because the sum P_{PZ}^{w}+P_{SP}^{w} and the sum P_{PZ}^{b}+P_{SP}^{b} are substantially the same at the point where the solid and dotted lines meet, the internal polarization field in InGaN channel layer 240 becomes approximately zero according to Equation (1). Accordingly, when the variable y is approximately 0.16, that is, a barrier layer has the composition of Al_{0.1}Ga_{0.74}In_{0.16}N, the internal polarization field becomes approximately zero.

The composition of InGaN channel layer 240 and AlInGaN barrier layer 235 can be controlled. The graph shown in FIG. 5 illustrates the relationship between the compositions of InGaN channel layer 240 and the compositions of AlGaInN barrier layer 235 when the internal polarization field is zero. Through experiments, the mole fractions of the compositions in InGaN channel layer 240 and AlGaInN barrier layer 235, in which the internal polarization field can be zero, can be determined.

For example, the mole fractions of In and Ga in InₓGa₁₋ₓN channel layer 240 can be controlled based on the mole fractions of Ga and In in Al_{0.1}Ga_{0.9-y}In_{y}N barrier layer 235. Here, the thickness of InₓGa₁₋ₓN channel layer 240 is about 3 nm, and the thickness of Al_{0.1}Ga_{0.9-y}In_{y}N barrier layer 235 is about 3 nm to 15 nm. As shown in the graph of FIG. 5, the internal polarization field can be approximately zero when the variables x and y are approximately 0.05 and 0.11, respectively. In this case, InₓGa₁₋ₓN channel layer 240 has the composition of In_{0.05}Ga_{0.95}N, and Al_{0.1}Ga_{0.9-y}In_{y}N barrier layer 235 has the composition of Al_{0.1}Ga_{0.79}In_{0.11}N. Further, when the variables x and y are approximately 0.10 and 0.16 or 0.15 and 0.21, the internal polarization field becomes zero. In the case where the variables x and y are approximately 0.10 and 0.16, InₓGa₁₋ₓN channel layer 240 and Al_{0.1}Ga_{0.9-y}In_{y}N barrier layer 235 have the compositions of In_{0.1}Ga_{0.9}N and Al_{0.1}Ga_{0.74}In_{0.16}N, respectively, and in the case where the variables x and y are approximately 0.15 and 0.21, InₓGa₁₋ₓN channel layer 240 and Al_{0.1}Ga_{0.9-y}In_{y}N barrier layer 235 have the compositions of In_{0.15}Ga_{0.85}N and Al_{0.1}Ga_{0.69}In_{0.21}N, respectively.

As shown in the graph of FIG. 5, In compositions in InₓGa₁₋ₓN channel layer 240 and Al_{0.1}Ga_{0.9-y}In_{y}N barrier layer 235 can have a linear relationship. Thus, the variables x and y can have a linear relationship. In other embodiments, mole fractions of certain elements of a channel layer and a barrier layer can show non-linear relationship, such as logarithmic or exponential relationship by controlling semiconductor materials or compositions of the semiconductor materials of a HEMT. In some embodiments, In compositions in InGaN channel layer 240 and AlGaInN barrier layer 235 can be selected based on the amount of the compressive strain in a layer. Since the higher In composition (e.g., about 0.3 or more) in InGaN channel layer 240 results in a larger compressive strain, and the growth of the strained layers is limited to a critical thickness, the lower In composition (e.g., about 0.01 to 0.30) in AlGaInN barrier layer 235 can be selected.

As described above, by controlling the composition of AlGaInN barrier layer 235 and InGaN channel layer 240, the internal polarization field can be effectively reduced. Further, minimization of the internal polarization field allows for a reduction of the carrier scattering rate, which allows for efficient carrier confinement and high electron mobility of HEMT 200.

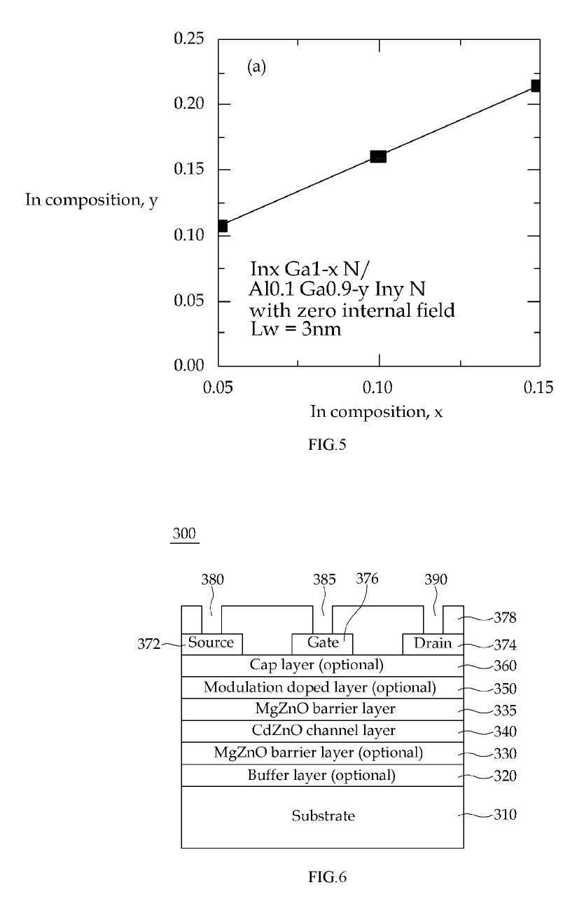

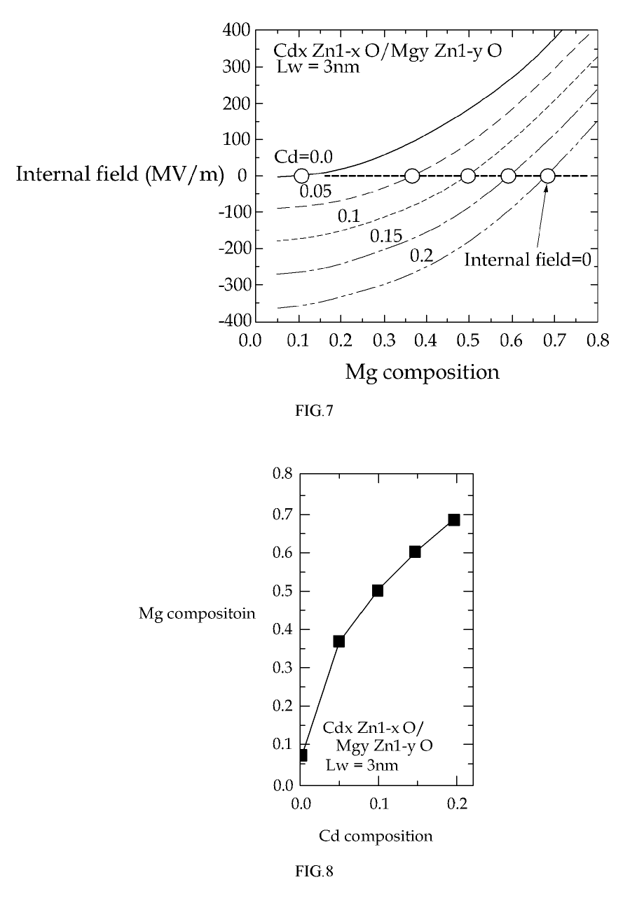

In another embodiment, a HEMT may have a II-VI compound semiconductor for its channel layer and barrier layers. Such a II-VI semiconductor based HEMT will be described with reference to FIGS. 6-8. FIG. 6 is a schematic diagram of an illustrative embodiment of a II-VI compound semiconductor material based HEMT 300. FIG. 7 is a graph showing internal polarization field as a function of magnesium (Mg) composition of a MgZnO barrier layer and cadmium (Cd) composition of a CdZnO channel layer shown in FIG. 6. FIG. 8 is a graph showing the relationship between Mg composition of the MgZnO barrier layer and Cd composition of the CdZnO channel layer shown in FIG. 6.

With reference to FIG. 6, II-VI semiconductor based HEMT 300 includes a substrate 310, a buffer layer 320 on substrate 310, a lower MgZnO barrier layer 330 on buffer layer 320, a CdZnO channel layer 340 on lower MgZnO barrier layer 330, an upper MgZnO barrier layer 335 on CdZnO channel layer 340, a modulation doped layer 350 on upper MgZnO barrier layer 335, a cap layer 360 on modulation doped layer 350, a source contact 372, a drain contact 374, and a gate contact 376 on cap layer 360, and a passivation layer 378 covering at least portions of the contacts (e.g., source contact 372, drain contact 374, and gate contact 376) and cap layer 360 not covered by the contacts. Passivation layer 378 has windows 380, 385 and 390 that expose at least a portion of the contacts and through which the contacts may connected, for example, to wire bonds (not shown). Here, band gaps of lower and upper MgZnO barrier layers 330 and 335 are greater than a band gap of CdZnO channel layer 340.

Although HEMT 300 is described as including two barrier layers (e.g., lower barrier layer 330 and upper barrier layer 335), lower barrier layer 330 is optional and HEMT 300 may include not include lower barrier layer 330 under CdZnO channel layer 340. Buffer layer 320, modulation doped layer 350, and cap layer 360 are also optional and can be omitted. Further, channel layer 340 may be composed of a II-VI semiconductor, such as ZnO, ZnS, CdO, CdS, CdZnS, MgZnO, MgZnS, CdMgZnO, and CdMgZnS. Channel layer 340 may have a thickness of several nanometers to several hundreds nanometers. The thickness of channel layer 340 may be about 0.1 nm to 300 nm, or about 1 nm to 50 nm.

Further, lower and upper barrier layers 330 and 335 may be composed of a II-VI group compound semiconductor material, such as CdZnO, CdZnS, MgZnS, CdMgZnO, and CdMgZnS. Lower and upper barrier layers 330 and 335 may each have a thickness of several nanometers to several hundreds nanometers. In some embodiments, upper and lower barrier layers 330 and 335 each may have a thickness of about 0.1 nm to 500 nm, or about 1 nm to 100 nm.

II-VI group compound semiconductor material of upper and lower barrier layers 335 and 330 have wider band gaps than that of II-VI group semiconductor material of channel layer 340 to form a quantum well in channel layer 340. Here, upper and lower MgZnO barrier layers 335 and 330 have a band gap of about 3.35 eV to 5.3 eV, and CdZnO channel layer 340 has a band gap of about 2.2 eV to 3.35 eV. The band gap of the semiconductor material of upper and lower MgZnO barrier layer 335 and 330 can be greater than that of the semiconductor material of CdZnO channel layer 340. Thus, due to the differences between the band gaps of CdZnO channel layer 340 and MgZnO barrier layers 330 and 335, a quantum well is formed in CdZnO channel layer 340.

As illustrated with respect to Equation (1) above, the internal polarization field in the quantum well can be reduced by controlling the mole fractions of compositions in CdZnO channel layer 340 and upper and lower MgZnO barrier layers 335 and 330, as shown in the graph of FIG. 7.

The graph shown in FIG. 7 illustrates the internal polarization field (y-axis) in CdZnO channel layer 340 for different Cd compositions and Mg compositions (x-axis). Here, it is assumed that CdZnO channel layer 340 has the composition of CdₓZn₁₋ₓO (0≦x≦1) and has the thickness of about 3 nm, and MgZnO lower and upper barrier layers 330 and 335 have the composition of Mg_{y}Zn_{1-y}O (0≦y≦1) and have the thickness of about 3 nm to 15 nm.

As illustrated with respect to FIG. 4 above, Cd and Zn compositions in CdₓZn₁₋ₓO channel layer 340, and Mg and Zn compositions in lower and upper Mg_{y}Zn_{1-y}O barrier layers 330 and 335 may be controlled to make the internal polarization field in CdₓZn₁₋ₓO channel layer 340 to be zero. For example, when Cd composition of CdₓZn₁₋ₓO channel layer 340 and Mg composition of lower and upper Mg_{y}Zn_{1-y}O barrier layers 330 and 335 have mole fractions of approximately zero and 0.1, respectively, that is, HEMT 300 has channel/barrier layers of ZnO/Mg_{0.1}Zn_{0.9}O, the internal polarization field becomes zero. In another example, the internal field becomes zero when the variables x and y are approximately 0.05 and 0.37, 0.1 and 0.5, 0.15 and 0.6, and 0.2 and 0.7, respectively. For example, in the case where the variables x and y are 0.2 and 0.7, respectively, HEMT 300 has channel/barrier layers of Cd_{0.2}Zn_{0.80}/Mg_{0.7}Zn_{0.3}O.

The relationship between Mg and Cd compositions is shown in graph of FIG. 8. In the graph, the solid line indicates when the internal polarization field is zero. As shown in the graph, Mg composition of lower and upper Mg_{y}Zn_{1-y}O barrier layers 330 and 335 can increase logarithmically in accordance with the increase of Cd composition of CdₓZn₁₋ₓO channel layer 340 in the condition of zero internal polarization field. In this case, Mg composition of lower and upper Mg_{y}Zn_{1-y}O barrier layers 330 and 335, and Cd composition of CdₓZn₁₋ₓO channel layer 340 are in a logarithmic relationship. In another embodiments, the relationship between the composition of barrier layers and the composition of a channel layer at the zero internal polarization field can be linearly or non-linearly (e.g., logarithmic, or exponential) depending on the type of the semiconductor materials and compositions thereof of a HEMT.

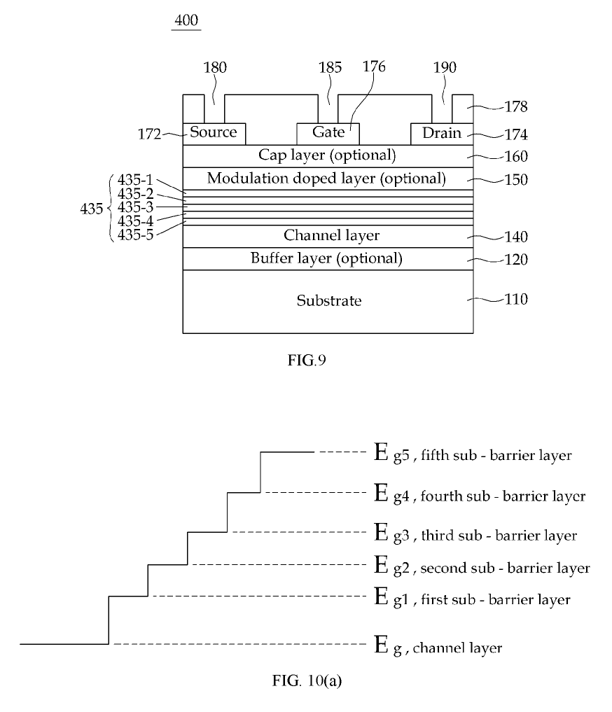

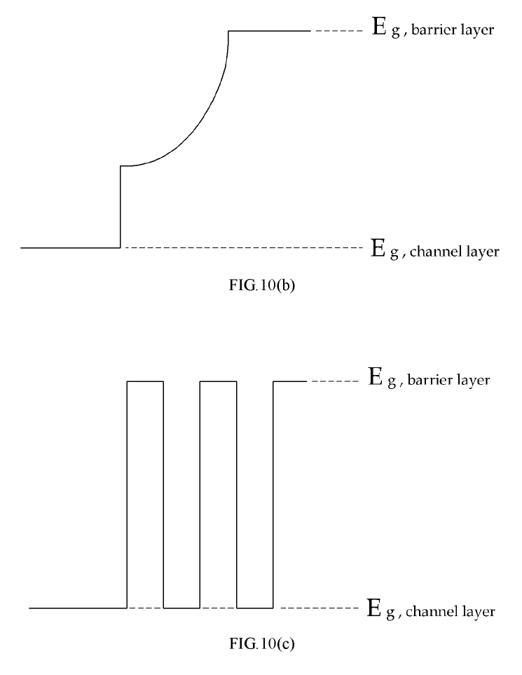

With reference to FIGS. 9 and 10(a) through 10(c), another illustrative embodiment of a HEMT will be described FIG. 9 shows an illustrative embodiment of a HEMT 400 having a multiple number of sub-barrier layers. FIGS. 10(a) through 10(c) illustrate examples of energy band gaps of the sub-barrier layers of HEMT 400. HEMT 400 shown in FIG. 9 has a configuration substantially similar to HEMT 100 shown in FIG. 1 except that HEMT 400 includes a barrier layer 435 composed of sub-barrier layers 435-1 to 435-n instead of barrier layer 135. The multiple sub-barrier layers provide for reduced strain between barrier layer 435 and channel layer 140. Also, unlike HEMT 100 shown in FIG. 1, HEMT 400 does not include lower barrier layer 130. Barrier layer 435, as shown in FIG. 9, is composed of a multiple number of sub-barrier layers (e.g., a sub-barrier layer 435-1, a sub-barrier layer 435-2, a sub-barrier layer 435-3, a sub-barrier layer 435-4, and a sub-barrier layer 435-5) on channel layer 140. The energy band gaps of sub-barrier layers 435-1 to 435-5 may be controlled to provide reduced strain in channel layer 440.

For example, the energy band gaps of sub-barrier layers 435-1 to 435-5 can be controlled to show a step shape, as shown in FIG. 10(a). In FIG. 10(a), E_{g, channel layer} refers to an energy band gap of channel layer 140 in FIG. 9, and E_{g1, first sub-barrier layer}, E_{g2, second sub-barrier layer}, E_{g3, third sub-barrier layer}, E_{g4, fourth sub-barrier layer} and E_{g5, fifth sub-barrier layer} refer to energy band gaps of sub-barrier layers 435-1 to 435-5, respectively. The step shape of the energy band gaps can be formed by controlling compositions in each sub-barrier layer. For example, assuming that channel layer 140 is composed of InGaN, and sub-barrier layers 435-1 to 435-5 are composed of AlₓIn_{y}Ga_{1-x-y}N, the step shape of the energy band gaps can be achieved by controlling first sub-barrier layer 435-1 to have the smallest mole fraction of Al composition among the mole fractions of Al compositions in sub-barrier layers 435-1 to 435-5, and sequentially increasing the mole fraction of Al composition of the other sub-barrier layers (i.e., sub-barrier layers 435-2 to 435-5) such that an upper sub-barrier layer has a higher mole fraction of Al composition than that of a sub-barrier layer immediately below, as shown in FIG. 10(a). In another embodiment, In composition (y) or both In and Al compositions (x and y) can be varied to control the energy band gap difference. Even in this case, the energy band gaps of the multiple sub-barrier layers 435-1 to 435-5 are greater than the energy band gap of channel layer 140, and the sum of spontaneous and piezoelectric polarizations at sub-barrier layers 435-1 to 435-5 may be controlled to be substantially identical to the sum of spontaneous and piezoelectric polarizations at a quantum well in channel layer 140, as described above.

Further, the composition of barrier layer 435 can be controlled to have a gradually increasing band gap, while being greater than the band gap of channel layer 140, as shown in FIG. 10(b). Here, barrier layer 435 can have a multiple number of sub-barrier layers, each sub-barrier layer having a slightly different composition from that of its adjacent sub-barrier layers in order to produce a gradually increasing band gap. Thus, the strain resulting from the steep difference of the energy band gaps of barrier layer 435 and channel layer 140 can be reduced by the multiple sub-barrier layers having the step energy band gap or the gradually increasing band gap.

Still another embodiment for energy band gaps of multiple sub-barrier layers 435-1 to 435-5 is shown in FIG. 10(c). Here, barrier layer 435 of HEMT 400 may be configured to have multiple first sub-barrier layers/multiple second sub-barrier layers. For example, second sub-barrier layers (e.g., a sub-barrier layer 435-1, a sub-barrier layer 435-3 and a sub-barrier layer 435-5) having a larger band gap than that of channel layer 140, and first sub-barrier layers (e.g., a sub-barrier layer 435-2 and a sub-barrier layer 435-4) having substantially the same band gap as channel layer 140 can be alternatively formed on buffer layer 120. For example, channel layer 140 and first sub-barrier layers 435-2 and 435-4 can be composed of InGaN, and second sub-barrier layers 435-1, 435-3 and 435-5 can be composed of AlInGaN. In this case, the energy band gaps of the quantum well in channel layer 140 and barrier layer 435 are as in the diagram of FIG. 10(c). This configuration can reduce the strain by absorbing the strain like a spring. For channel layer 140 and barrier layer 435 having multiple first sub-barrier layers/multiple second sub-barrier layers, the sum of spontaneous and piezoelectric polarizations at barrier layer 435 may be controlled to be substantially identical to the sum of spontaneous and piezoelectric polarizations at the quantum well in channel layer 140, as described above.

Although five (5) sub-barrier layers (or sub-channel/sub-barrier layers) are illustrated, a different number of sub-barrier layers can be employed to reduce the strain that may be generated between channel layer 140 and barrier layer 435. Further, one of ordinary skill in the art will understand that various configurations of the energy band gaps of the sub-barrier layers can be used to reduce the strain, and that these various configurations of the energy band gaps are explicitly contemplated within the scope of the present disclosure.

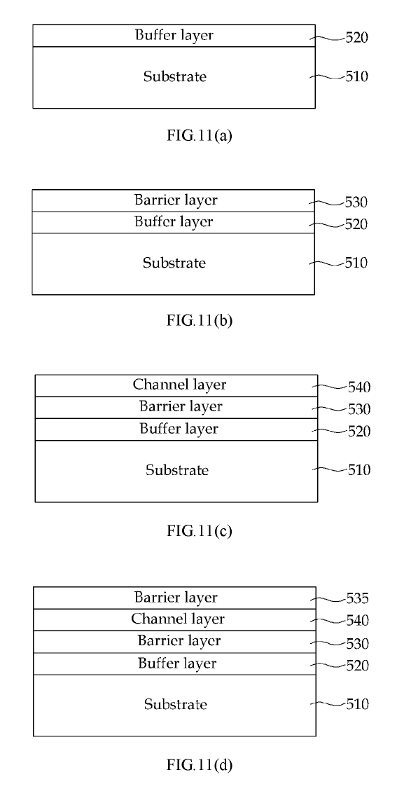

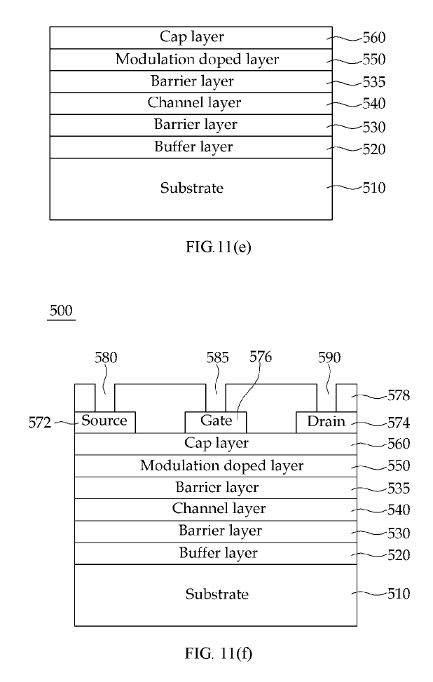

With reference to FIGS. 11(a) through 11(f), an illustrative embodiment of a method for fabricating a HEMT will now be described. FIGS. 11(a) through 11(f) are schematic diagrams illustrating an illustrative embodiment of a method for fabricating a HEMT 500 (shown in FIG. 11(f)). Although different figure reference numbers are used, it is assumed that HEMT 500 has substantially the same or similar components to those of HEMT 100 of FIG. 1.

As depicted in FIG. 11(a), a substrate 510 is provided. Suitable materials for substrate 510 are substantially the same as the materials described above for substrate 100. A buffer layer 520 can be optionally formed on substrate 510. Suitable materials for buffer layer 520 are substantially the same as the materials described above for buffer layer 120. Buffer layer 520 can be formed using any of a variety of well-known deposition techniques or epitaxy techniques, such as radio-frequency (RF) magnetron sputtering, pulsed laser deposition, metal organic chemical vapor deposition (MOCVD), molecular beam epitaxy, or radio-frequency plasma-excited molecular beam epitaxy.

A lower barrier layer 530 can be optionally formed over buffer layer 520, as depicted in FIG. 11(b). Lower barrier layer 530 can include a ternary or a quaternary semiconductor. Suitable materials and thicknesses of lower barrier layer 530 are substantially the same as described above for lower barrier layer 130. Lower barrier layer 530 can be formed using any of the aforementioned well-known deposition techniques or epitaxy techniques. The composition of lower barrier layer 530 can be adjusted by controlling the amount of precursor gases provided to a deposition device (e.g. MOCVD device) or by controlling the processing temperature or processing time.

As depicted in FIG. 11(c), a channel layer 540 is formed over lower barrier layer 530. Channel layer 540 can be formed of a III-V group semiconductor material or a II-VI group semiconductor material. The III-V group semiconductor material or II-VI group semiconductor material of channel layer 540 has a smaller band gap than that of the semiconductor material of lower barrier layer 530 to form a quantum well in channel layer 540. Suitable materials and thicknesses of channel layer 540 are substantially the same as described above for channel layer 140. Channel layer 540 can be formed using any of the aforementioned well-known deposition techniques or epitaxy techniques.

As depicted in FIG. 11(d), an upper barrier layer 535 is formed over channel layer 540. Suitable materials and thicknesses of upper barrier layer 535 are substantially the same as described above for upper barrier layer 135. Upper barrier layer 535 can be formed using any of the aforementioned well-known deposition techniques or epitaxy techniques. To produce the various band gap configuration depicted in FIGS. 10(a) through (c), the composition of upper barrier layer 535 can be adjusted by controlling the amount of precursor gases provided to a deposition device (e.g. MOCVD device) or by controlling the processing temperature or processing time.

As depicted in FIG. 11(e), a modulation doped layer 550 can be optionally formed over upper barrier layer 535. Suitable materials and thicknesses of modulation doped layer 550 are substantially the same as described above for modulation doped layer 150. In some embodiments, a cap layer 560 may be optionally formed on modulation doped layer 550. Suitable materials and thicknesses of cap layer 560 are substantially the same as described above for cap layer 160. Modulation doped layer 550 and cap layer 560 can be formed using any of the aforementioned well-known deposition techniques or epitaxy techniques.

As depicted in FIG. 11(f), a source contact 572, a drain contact 574 and a gate contact 576 can be formed on cap layer 560. Contacts 572, 574, and 576 are substantially similar to contacts 172, 174, and 176, respectively, described above. Contacts 572, 574, and 576 can be formed using any of a variety of well-known technique. For example, a first metal layer (not shown) can be formed on cap layer 560 by using any of a variety of well-known metal forming techniques, such as sputtering, electroplating, e-beam evaporation, thermal evaporation, laser-induced evaporation, or ion-beam induced evaporation. The first metal layer can be selectively etched to form gate contact 576, thereby exposing portions of cap layer 560 on which gate contract 576 is not formed. Then, a second metal layer (not shown) can be formed over the exposed portions of cap layer 560 and gate contact 576. The second metal layer can be selectively etched to form source and drain contacts 572 and 574. In another embodiment, an additional layer (not shown) for facilitating an ohmic contact of source and drain contacts 572 and 574 can be formed between cap layer 560 and source and drain contacts 572 and 574.

A passivation layer 578 can be formed to cover source, drain, and gate contacts 572, 574, and 576. Passivation layer 578 can be formed of silicon nitride or silicon dioxide by utilizing, for example, but not limitation, low pressure or plasma-enhanced chemical vapor deposition (LPCVD or PECVD). Passivation layer 578 can be etched to have windows 580, 585, and 590 through which contacts (e.g., source contact 572, drain contact 574, and gate contact 576) may be connected to respective wire bonds (not shown).

Accordingly, HEMT 500 in accordance with some embodiments can reduce the internal polarization field in a quantum well by forming one or more barrier layers of II-VI group compound semiconductor materials on a channel layer of II-VI group compound semiconductor materials, or one or more barrier layers of III-V group compound semiconductor materials on a channel layer of III-V group compound semiconductor materials. Further, II-VI or III-V semiconductor based HEMTs can reduce the internal polarization field in a quantum well by controlling the mole fractions of a II-VI group compound semiconductor material or a III-V group compound semiconductor material in the channel layer or the barrier layers. Through reduction of the internal polarization field in the quantum well, the electron mobility of the HEMT can be increased, and thus a high performance and high application of the HEMT can be achieved.

One skilled in the art will appreciate that, for this and other processes and methods disclosed herein, the functions performed in the processes and methods may be implemented in differing order. Furthermore, the outlined steps and operations are only provided as examples, and some of the steps and operations may be optional, combined into fewer steps and operations, or expanded into additional steps and operations without detracting from the essence of the disclosed embodiments.

The present disclosure is not to be limited in terms of the particular embodiments described in this application, which are intended as illustrations of various aspects. Many modifications and variations can be made without departing from its spirit and scope, as will be apparent to those skilled in the art. Functionally equivalent methods and apparatuses within the scope of the disclosure, in addition to those enumerated herein, will be apparent to those skilled in the art from the foregoing descriptions. Such modifications and variations are intended to fall within the scope of the appended claims. The present disclosure is to be limited only by the terms of the appended claims, along with the full scope of equivalents to which such claims are entitled. It is to be understood that this disclosure is not limited to particular methods, reagents, compounds compositions or biological systems, which can, of course, vary. It is also to be understood that the terminology used herein is for the purpose of describing particular embodiments only, and is not intended to be limiting.

With respect to the use of substantially any plural and/or singular terms herein, those having skill in the art can translate from the plural to the singular and/or from the singular to the plural as is appropriate to the context and/or application. The various singular/plural permutations may be expressly set forth herein for sake of clarity.

It will be understood by those within the art that, in general, terms used herein, and especially in the appended claims (e.g., bodies of the appended claims) are generally intended as “open” terms (e.g., the term “including” should be interpreted as “including but not limited to,” the term “having” should be interpreted as “having at least,” the term “includes” should be interpreted as “includes but is not limited to,” etc.). It will be further understood by those within the art that if a specific number of an introduced claim recitation is intended, such an intent will be explicitly recited in the claim, and in the absence of such recitation no such intent is present. For example, as an aid to understanding, the following appended claims may contain usage of the introductory phrases “at least one” and “one or more” to introduce claim recitations. However, the use of such phrases should not be construed to imply that the introduction of a claim recitation by the indefinite articles “a” or “an” limits any particular claim containing such introduced claim recitation to embodiments containing only one such recitation, even when the same claim includes the introductory phrases “one or more” or “at least one” and indefinite articles such as “a” or “an” (e.g., “a” and/or “an” should be interpreted to mean “at least one” or “one or more”); the same holds true for the use of definite articles used to introduce claim recitations. In addition, even if a specific number of an introduced claim recitation is explicitly recited, those skilled in the art will recognize that such recitation should be interpreted to mean at least the recited number (e.g., the bare recitation of “two recitations,” without other modifiers, means at least two recitations, or two or more recitations). Furthermore, in those instances where a convention analogous to “at least one of A, B, and C, etc.” is used, in general such a construction is intended in the sense one having skill in the art would understand the convention (e.g., “a system having at least one of A, B, and C” would include but not be limited to systems that have A alone, B alone, C alone, A and B together, A and C together, B and C together, and/or A, B, and C together, etc.). In those instances where a convention analogous to “at least one of A, B, or C, etc.” is used, in general such a construction is intended in the sense one having skill in the art would understand the convention (e.g., “a system having at least one of A, B, or C” would include but not be limited to systems that have A alone, B alone, C alone, A and B together, A and C together, B and C together, and/or A, B, and C together, etc.). It will be further understood by those within the art that virtually any disjunctive word and/or phrase presenting two or more alternative terms, whether in the description, claims, or drawings, should be understood to contemplate the possibilities of including one of the terms, either of the terms, or both terms. For example, the phrase “A or B” will be understood to include the possibilities of “A” or “B” or “A and B.”

In addition, where features or aspects of the disclosure are described in terms of Markush groups, those skilled in the art will recognize that the disclosure is also thereby described in terms of any individual member or subgroup of members of the Markush group.

As will be understood by one skilled in the art, for any and all purposes, such as in terms of providing a written description, all ranges disclosed herein also encompass any and all possible subranges and combinations of subranges thereof. Any listed range can be easily recognized as sufficiently describing and enabling the same range being broken down into at least equal halves, thirds, quarters, fifths, tenths, etc. As a non-limiting example, each range discussed herein can be readily broken down into a lower third, middle third and upper third, etc. As will also be understood by one skilled in the art all language such as “up to,” “at least,” and the like include the number recited and refer to ranges which can be subsequently broken down into subranges as discussed above. Finally, as will be understood by one skilled in the art, a range includes each individual member. Thus, for example, a group having 1-3 cells refers to groups having 1, 2, or 3 cells. Similarly, a group having 1-5 cells refers to groups having 1, 2, 3, 4, or 5 cells, and so forth.

From the foregoing, it will be appreciated that various embodiments of the present disclosure have been described herein for purposes of illustration, and that various modifications may be made without departing from the scope and spirit of the present disclosure. Accordingly, the various embodiments disclosed herein are not intended to be limiting, with the true scope and spirit being indicated by the following claims.

1. A high electron mobility transistor (HEMT) comprising:
a channel layer composed of a first compound semiconductor material; and
one or more barrier layers disposed on either one side or both sides of the channel layer and composed of a second compound semiconductor material, wherein the composition of the barrier layer is adjusted to reduce an internal polarization field in the channel layer.

2. The HEMT of claim 1, wherein a band gap of the first compound semiconductor material is smaller than that of the second compound semiconductor material.

3. The HEMT of claim 1, wherein the second compound semiconductor material comprises a ternary or a quaternary compound semiconductor material.

4. The HEMT of claim 1, wherein the first and second compound semiconductor materials each comprise a III-V compound semiconductor material or a II-VI compound semiconductor material.

5. The HEMT of claim 1, wherein the first compound semiconductor material comprises GaN, InGaN, CdZnO, AlN, AlP, AlAs, GaP, GaAs, InN, InP, InAs, AlGaN, AlGaP, AlGaAs, InGaN, InGaP, InGaAs, InAlN, InAlP, InAlAs, AlGaInN, AlGaInP, AlGaInAs, ZnO, ZnS, CdO, CdS, CdZnS, MgZnO, MgZnS, CdMgZnO, or CdMgZnS.

6. The HEMT of claim 1, wherein the second compound semiconductor material comprises AlInGaN, MgZnO, InGaN, CdZnO, AlGaN, AlGaP, AlGaAs, InGaN, InGaP, InGaAs, InAlN, InAlP, InAlAs, AlGaInP, AlGaInAs, CdZnS, MgZnS, CdMgZnO, or CdMgZnS.

7. The HEMT of claim 1, further comprising a gate contact, a source contact, and a drain contact disposed on the barrier layer.

8. The HEMT of claim 1, wherein the barrier layer comprises a plurality of sub-barrier layers, each of the sub-barrier layers composed of a III-V compound semiconductor material or a II-VI compound semiconductor material.

9. The HEMT of claim 8, wherein each of the sub-barrier layers comprises AlInGaN, MgZnO, InGaN, CdZnO, AlGaN, AlGaP, AlGaAs, InGaN, InGaP, InGaAs, InAlN, InAlP, InAlAs, AlGaInP, AlGaInAs, CdZnS, MgZnS, CdMgZnO, or CdMgZnS.

10. The HEMT of claim 8, wherein the band gaps of the sub-barrier layers are adjusted to reduce the internal polarization field in the channel layer.

11. The HEMT of claim 10, wherein the composition of each sub-barrier layer is controlled to have a step shape band gap, a gradually increasing band gap, or a multi-quantum well band gap.

12. The HEMT of claim 1, wherein the channel layer is composed of InₓGa₁₋ₓN (0≦x≦1) and the barrier layer is composed of AlIn_{y}Ga_{1-y}N (0≦y≦1).

13. The HEMT of claim 12, wherein x is in the range of about 0 and 0.30 and y is in the range of about 0.01 and 0.30.

14. The HEMT of claim 1, wherein the channel layer is composed of CdₓZn₁₋ₓO (0≦x≦1) and the barrier layer is composed of Mg_{y}Zn_{1-y}O (0≦y≦1).

15. The HEMT of claim 14, wherein x is in the range of about 0 and 0.20 and y is in the range of about 0.01 and 0.80.

16. The HEMT of claim 12, wherein the relation of x and y is linear.

17. The HEMT of claim 14, wherein the relation of x and y is logarithmic.

18. The HEMT of claim 1, wherein the thickness of the channel layer is in the range of about 0.1 nm and 300 nm.

19. The HEMT of claim 1, wherein the thickness of the barrier layer is in the range of about 0.1 nm and 500 nm.

20. A method for fabricating a high electron mobility transistor (HEMT) comprising:
forming a channel layer composed of a first compound semiconductor material; and
forming one or more barrier layers on either one side or both sides of the channel layer, the barrier layer composed of a second compound semiconductor material, wherein the composition of the barrier layer is adjusted to reduce an internal polarization field in the channel layer.

21. The method of claim 20, wherein the first and second compound semiconductor materials each comprise a III-V compound semiconductor material or a II-VI compound semiconductor material.

22. The method of claim 20, wherein forming one or more barrier layers comprises forming a plurality of sub-barrier layers on either one side or both sides of the channel layer, each of the sub-barrier layers composed of a III-V compound semiconductor material or a II-VI compound semiconductor material.
